(19) United States
(12) Patent Application Publication
(10) Pub. No.: US 2015/0263282 A1
(43) Pub. Date: Sep. 17, 2015

(54) METHOD FOR FABRICATING SEMICONDUCTOR APPARATUS

(71) Applicant: SK Hynix Inc., Gyeonggi-do (KR)

(72) Inventors: Yong Hun SUNG, Gyeonggi-do (KR); Kwon HONG, Gyeonggi-do (KR); Su Jin CHAE, Gyeonggi-do (KR); Hyun Seok KANG, Gyeonggi-do (KR); Ji Won MOON, Gyeonggi-do (KR)

(21) Appl. No.: 14/296,133

(22) Filed: Jun. 4, 2014

(30) Foreign Application Priority Data
Mar. 17, 2014 (KR) 10-2014-0031047

(51) Int. Cl. H01L 45/00; H01L 21/285

(52) U.S. Cl. CPC H01L 45/16; H01L 21/28506

(57) ABSTRACT

A method for fabricating a semiconductor apparatus includes setting a semiconductor substrate in a process chamber, increasing an internal temperature of the process chamber to a predetermined temperature for pyrolyzing a source gas, supplying the source gas to the inside of the process chamber and pyrolyzing ions of the source gas to remain on the semiconductor substrate, and forming the ohmic contact layer by supplying a reaction gas to the inside of the process chamber, wherein the reaction gas is reacted with non-metal ions pyrolyzed from source gas.

### CROSS-REFERENCES TO RELATED APPLICATION

This application claims priority under 35 U.S.C. 119(a) to Korean application No. 10-2014-0031047, filed on Mar. 17, 2014, in the Korean intellectual property Office, which is incorporated by reference in its entirety as set forth in full.

### BACKGROUND

1. Technical Field

Various embodiments of the inventive concept relate to a method for fabricating a semiconductor apparatus, and more particularly, to a method for fabricating a semiconductor apparatus including a uniform metal silicide layer having a thin thickness.

2. Related Art

The penetration rate of digital apparatuses is increasingly growing and there are demands for memory devices with ultra-high integration, ultra-high speed, and ultra-low power, which are built in digital apparatuses in order to process large amounts of data at high speed in a limited area.

To meet the demands, variable resistive memory devices using a resistance material as a memory medium have been suggested. Typical examples of variable resistive memory devices are ferroelectric random access memories (FRAMs), magnetoresistive RAMs (MRAMs), or phase-change RAMs (PCRAMs).

A variable resistive memory device may be typically formed of a switching device and a resistance device, and may be implemented with a single-level cell (SLC) or a multi-level cell (MLC).

In particular, PCRAM includes a phase-change material layer which is stabilized to either a crystalline state or an amorphous state by heat, and switched between the two different resistance states.

Hereinafter, a general structure of a PCRAM will be described with reference to the accompanying drawings.

The PCRAM has a structure in which a switching device layer, an ohmic contact layer, a lower electrode, a phase-change material layer, and an upper electrode are sequentially formed on a semiconductor substrate.

The ohmic contact layer in the PCRAM structure is provided to reduce the electric contact resistance between the switching device layer and the lower electrode, and may generally include a metal silicide layer.

The metal silicide layer may be formed through a physical vapor deposition (PVD) method or a direct current plasma-assisted chemical vapor deposition (CVD) method.

A metal silicide layer produced through the PVD method may be formed by thickly depositing a metal layer, and performing a post-heat treatment process on the metal layer. However, the post-heat treatment makes it difficult to form a uniform metal silicide layer.

When the metal silicide layer is formed through the direct current plasma-assisted CVD method, the metal is grown by a vapor reaction and simultaneously the metal silicide layer is formed by a reaction with the silicon (Si) surface. As the metal reaction is increased by plasma or high-temperature deposition, the direct-current plasma-assisted CVD method makes it difficult to form a uniform metal silicide layer due to poor step coverage.

### SUMMARY

According to an exemplary embodiment of the present invention, a method for fabricating a semiconductor apparatus including an ohmic contact layer is provided. The method may include setting a semiconductor substrate in a process chamber, increasing the internal temperature of the process chamber to a predetermined temperature for pyrolyzing a source gas, remaining pyrolyzed ions of the source gas on the semiconductor substrate by supplying the source gas to the inside of the process chamber and pyrolyzing ions of the source gas, and forming the ohmic contact layer by supplying a reaction gas to the inside of the process chamber and supplying an inert gas to the process chamber to form a plasma atmosphere, wherein the reaction gas is reacts with non-metal ions pyrolyzed from the source gas in a plasma atmosphere.

According to an exemplary embodiment of the present invention, a method for fabricating an ohmic contact layer on a switching device layer of a phase changeable random access memory (PCRAM) is provided. The method may include providing a chemical vapor deposition (CVD) chamber, setting a substrate on which the switching device layer is formed in the CVD chamber, increasing the temperature of the CVD chamber to a first temperature, supplying a source gas including a metal material and other materials to the CVD chamber, wherein the source gas is pyrolyzed by the first temperature of the chamber, supplying a reaction gas and an inert gas to the CVD chamber, wherein the reaction gas reacts with the other materials on the switching device to be removed therefrom, and purging the inside of the chamber using a purge gas.

According to an exemplary embodiment of the present invention, a method for fabricating a semiconductor apparatus is provided. The method may include supplying a source gas including a metal material at a predetermined temperature to a semiconductor substrate in a chamber and depositing the source gas on the semiconductor substrate, and removing materials deposited on the semiconductor substrate other than the metal material by reacting a reaction gas with deposited materials.

These and other features, aspects, and embodiments are described below in the section entitled “DETAILED DESCRIPTION”.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a schematic cross-sectional view illustrating a semiconductor apparatus according to an embodiment of the inventive concept;

FIG. 2 is a flowchart illustrating a method for fabricating a semiconductor apparatus according to an embodiment of the inventive concept;

FIG. 3 is a schematic diagram illustrating fabrication equipment where an ohmic contact layer fabrication method of a semiconductor apparatus is performed according to an embodiment of the inventive concept; and

FIG. 4 is a waveform diagram illustrating a supply pattern of process gas in a fabrication method of a semiconductor apparatus according to an embodiment of the inventive concept.

### DETAILED DESCRIPTION

Exemplary embodiments are described herein with reference to schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes illustrated herein but may include deviations in shapes that result, for example, from manufacturing. In the drawings, lengths and widths of layers and regions may be exaggerated for clarity. Like reference numerals in the drawings denote like elements. It is also understood that when a layer is referred to as being “on” another layer or substrate, it can be directly on the other or substrate, or intervening layers may also be present. It is also noted that in this specification, “connected/coupled” refers to one component not only directly coupling another component but also indirectly coupling another component through an Intermediate component. In addition, the singular form may include a plural form, and vice versa, as long as it is not specifically mentioned.

The inventive concept is described herein with reference to cross-section and/or plan illustrations of embodiments of the inventive concept. However, embodiments of the inventive concept should not be construed as limiting the inventive concept. Although a few embodiments of the inventive concept will be shown and described, it will be appreciated by those of ordinary skill in the art that changes may be made in these exemplary embodiments without departing from the principles and spirit of the inventive concept.

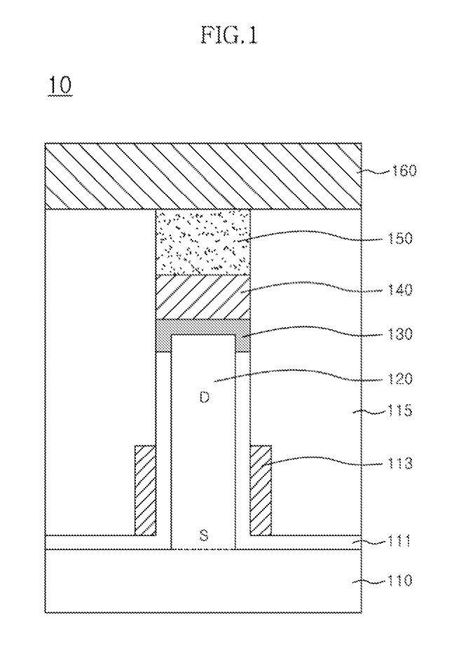

Hereinafter, an exemplary embodiment of the inventive concept, for example, a PCRAM will be described. FIG. 1 illustrates a semiconductor apparatus according to an embodiment of the inventive concept.

Referring to FIG. 1, a semiconductor apparatus 10 according to an embodiment of the inventive concept may include a switching device layer 120 formed on a semiconductor substrate 110, an ohmic contact layer 130 formed on the switching device layer 120, a lower electrode 140 formed on the ohmic contact layer 130, a phase-change material layer 150 formed on the lower electrode 140, and an upper electrode 160 formed on the phase-change material layer 150.

The ohmic contact layer 130 in a structure of the semiconductor apparatus 10 is provided to reduce electrical resistance between the switching device layer 120 and the lower electrode 140. The ohmic contact layer 130 may be provided to cover an upper surface and a sidewall of the switching device layer 120 which is formed on the semiconductor substrate. The switching device layer 120 may have a pillar structure and include a silicon material. This is because the ohmic contact layer 130 increases the contact area with the lower electrode 140 to reduce contact resistance with the lower electrode 140, and to increase an ON current due to reduction in the contact resistance.

The ohmic contact layer 130 may include a metal silicide layer. For example, the ohmic contact layer 130 may be formed of a titanium silicide layer.

The reference numerals 111, 113, and 115 denote a gate insulating layer, a gate electrode, and an inter-dielectric layer, respectively.

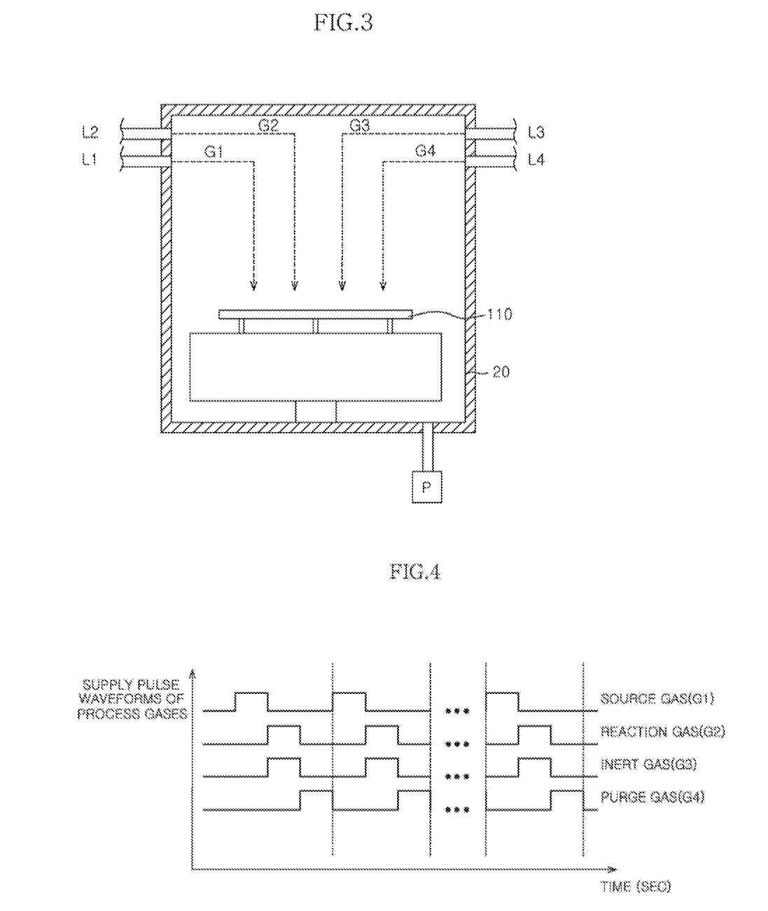

A process for forming an ohmic contact layer of a semiconductor apparatus according to an embodiment of the inventive concept will be described with reference to FIGS. 1 to 3.

First, the semiconductor substrate 110 including the switching device layer 120 is arranged in a process chamber 20 (S110). The process chamber 20 may be a chemical vapor deposition (CVD) chamber.

Next, in the temperature is raised in the process chamber 20 (S120). For example, the inside of the process chamber 20 may be set to a temperature of 450° C. to 1000° C. at a rate of 5 to 20° C./sec. The temperature may be a pyrolyzing temperature of a source gas for forming a metal silicide layer. Further, the pressure of the process chamber 20 may be about 0.5˜20 Torr.

The source gas G1 is supplied to the inside of the process chamber 20 for through a first pipe L1 (S130). The source gas G1 may be selected from the group consisting of gases containing a metal precursor and an organic metal precursor. For example, the source gas G1 may be TiCl₄ gas, and may be provided to the inside of the process chamber 20 at a flow rate of 1 to 1000 sccm.

When the source gas G1 is supplied as a high-temperature environment is created in the process chamber 20 as described above, a precursor of the source gas G1 may be pyrolyzed into metal ions and non-metal ions inside of the process chamber 20, and the metal ions and non-metal ions may be deposited on the switching device layer 120. For example, when the source gas G1 includes TiCl₄ gas, Ti metal ions and Cl ions may be pyrolyzed and absorbed on the semiconductor substrate 110 having the switching device layer 120.

Next, a reaction gas G2 is supplied to inside the process chamber 20 for a given time through a second pipe L2 (S140), and simultaneously a plasma atmosphere is created in the process chamber 20 (S150). The reaction gas G2 may Include at least one selected from the group consisting of H₂ gas, NH₃ gas, and F gas.

The reaction gas G2 may react with one of the ions remaining on the semiconductor substrate 110 in the plasma atmosphere. For example, when the reaction gas G2 includes H₂ gas, the H₂ gas may react with Cl ions (Cl⁻) remaining on the semiconductor substrate 110 in the plasma atmosphere, and the Cl ions may be removed. Only non-reacted Ti metal ions are left on the semiconductor substrate 110.

In the above-described process, to create the plasma atmosphere in the process chamber 20, an inert gas G3 may be supplied through a third pipe L3. The inert gas G3 may include one selected from the group consisting of Ar, He, Ne, Kr, Xe, and Rn gas.

The Cl ions reacted with the reaction gas G2, that is, HCl gas and the inert gas G3 may be vented by continuously pumping them out of the process chamber 20.

Next, a purge gas G4 is supplied to inside of the process chamber 20 through a fourth pipe L4 (S160). When the purge gas G4 is supplied, a reduction in temperature inside the process chamber 20 may occur.

The above-described sequences S120 to S160 may suppress a vapor reaction of the reaction gas G2 and the source gas G1 and react the reaction gas G2 with non-metal ions (Cl ions) of the source gas G1 on a surface of the semiconductor substrate 110 to uniformly form a metal silicide layer (Ti metal ions) on the semiconductor substrate 110 including the switching device layer 120.

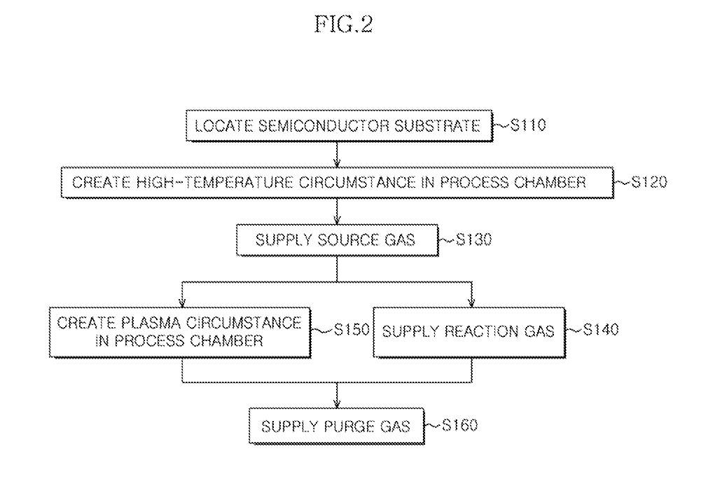

Referring to FIGS. 2 and 4, a thin metal silicide may be smoothly formed by repeatedly performing the above-described sequences. That is, when the sequences S120 to S160 are defined as one cycle, the metal silicide layer having a predetermined thickness may be formed by repeatedly performing the cycle.

For example, when a process of forming a metal silicide layer having a thickness of 10 Å is defined as one cycle, 10 cycles may be repeatedly performed to form a metal silicide layer with a thickness of 100 Å. In the embodiment, a process of forming a thin metal silicide layer may be repeatedly performed to form a uniform metal silicide layer having a predetermined thickness.

As described above, in the embodiment, ions of the source gas G1 are deposited on the semiconductor substrate 110 by pyrolyzing the source gas G1 in the process chamber 20 at high temperatures, and the uniform metal silicide layer may be formed using the metal ions deposited on the semiconductor substrate 110 by reacting the reaction gas G2 with the deposited non-metal ions in a plasma atmosphere.

The embodiment may smoothly form a thin but uniform metal silicide layer having a predetermined thickness by repeatedly performing the above-described process.

The above embodiment of the present invention is illustrative and not limitative. Various alternatives and equivalents are possible. The invention is not limited by the embodiments described herein, nor is the invention limited to any specific type of semiconductor device. Other additions, subtractions, or modifications are obvious in view of the present disclosure and are intended to fall within the scope of the appended claims.

What is claimed is:

1. A method for fabricating a semiconductor apparatus including an ohmic contact layer, the method comprising:
setting a semiconductor substrate in a process chamber;
increasing an internal temperature of the process chamber to a predetermined temperature for pyrolyzing a source gas;
remaining pyrolyzed ions of the source gas on the semiconductor substrate by supplying the source gas to the process chamber and pyrolyzing ions of the source gas; and
forming the ohmic contact layer by supplying a reaction gas to the process chamber and supplying an inert gas to the process chamber to form a plasma atmosphere, wherein the reaction gas reacts with non-metal ions pyrolyzed from the source gas in a plasma atmosphere.

2. The method of claim 1, wherein the semiconductor substrate includes a switching device layer.

3. The method of claim 1, wherein the predetermined temperature includes temperatures from 450° C. to 1000° C.

4. The method of claim 1, further comprising:
supplying a purge gas to the process chamber.

5. The method of claim 4, further comprising:
repeatedly increasing of the temperature of the process chamber, the supplying of the source gas, the forming of the ohmic contact layer, and the supplying of the purge gas to form the ohmic contact layer with a predetermined thickness.

6. The method of claim 1, wherein the source gas includes a metal ion to be formed as the ohmic contact layer.

7. The method of claim 6, wherein the reaction gas includes one selected from the group consisting of H₂ gas, NH₃ gas, and F gas, and
wherein the reaction gas is provided for removing the non-metal ions of the source gas.

8. A method for fabricating an ohmic contact layer on a switching device layer of a phase changeable random access memory (PCRAM), comprising:
providing a chemical vapor deposition (CVD) chamber;
setting a substrate on which the switching device layer is formed in the CVD chamber;
increasing a temperature of the CVD chamber to a first temperature;
supplying a source gas including a metal material and other materials to the CVD chamber, wherein the source gas is pyrolyzed by the first temperature of the chamber;
supplying a reaction gas and an inert gas to the CVD chamber, wherein the reaction gas reacts with the other materials on the switching device to be removed therefrom; and
purging an inside of the chamber using a purge gas.

9. The method of claim 8, wherein the first temperature is 450° C. to 1000° C.

10. The method of claim 8, wherein a plasma atmosphere is created in the chamber when the inert gas is supplied.

11. The method of claim 8, wherein the switching device layer includes a silicon material.

12. The method of claim 11, wherein the switching device layer includes a pillar structure.

13. A method for fabricating a semiconductor apparatus, comprising:
supplying a source gas including a metal material at a predetermined temperature to a semiconductor substrate in a chamber and depositing materials of the source gas on the semiconductor substrate; and
removing materials deposited on the semiconductor substrate other than the metal material by reacting a reaction gas with deposited materials.

14. The method of claim 13, wherein the removing of the materials includes:
supplying a reaction gas to the semiconductor substrate in the chamber; and
supplying an inert gas to the semiconductor substrate in the chamber to form a plasma therein.

15. The method of claim 13, wherein the source gas is pyrolyzed into the metal material and the other materials at the predetermined temperature.
